(19) United States
(12) Patent Application Publication
(10) Pub. No.: US 2023/0198454 A1
(43) Pub. Date: Jun. 22, 2023

(54) A WINDOW UNIT FOR A BUILDING OR STRUCTURE

(71) Applicant: CLEARVUE TECHNOLOGIES LTD, West Perth (AU)

(72) Inventor: Steven COONEN, Grass Valley, CA (US)

(73) Assignee: CLEARVUE TECHNOLOGIES LTD, West Perth (AU)

(21) Appl. No.: 17/999,480

(22) PCT Filed: May 21, 2021
(86) PCT No.: PCT/AU2021/050485

§ 371 Date: Nov. 21, 2022

(30) Foreign Application Priority Data
May 21, 2020 (AU) 2020901648
Nov. 6, 2020 (AU) 2020904059

(51) Int. Cl. H02S 20/22; H02S 40/22; E06B 7/28; E06B 3/66

(52) U.S. Cl. CPC H02S 20/22; E06B 3/66; E06B 7/28; H02S 40/22; H01L 31/0488

(57) ABSTRACT

The present disclosure provides a window unit for a building or structure. The window unit is arranged for generating electricity and comprises a panel having an area that is transparent for at least a portion of visible light and having a light receiving surface for receiving light from a light incident direction. The window unit further comprises at least one series of solar cells, each solar cell being a bifacial solar cell and having opposite first and second surfaces each having an area in which light can be absorbed to generate electricity, the solar cells being positioned such that in use the first surfaces are oriented to receive light from the light incident direction and the second surfaces receive light from an opposite direction.

### CROSS REFERENCE TO RELATED APPICATIONS

This application is a national stage filing under section 371 of International Application No. PCT/AU2021/050485, filed on May 21, 2021, and published on Nov. 25, 2021 as WO 2021/232114, which claims priority to Australian Application No. AU 2020901648, filed May 21, 2020 and also claims priority to Australian Application No. AU 2020904059, filed Nov. 6, 2020. The entire contents of each application are incorporated herein by reference in their entireties.

### FIELD OF THE INVENTION

The present disclosure relates to a window unit for a building or structure and relates particularly to a window unit for a building or structure which generates electricity.

### BACKGROUND OF THE INVENTION

Buildings such as office towers, high-rise housings and hotels use large amounts of exterior window panelling and/or facades which incorporate glass panelling.

Overheating of interior spaces, such as spaces that receive sunlight through such window panels, is a problem that may be overcome using air conditioners. A large amount of energy is globally used to operate air conditioners.

PCT international applications numbers PCT/AU2012/000778, PCT/AU2012/000787 and PCT/AU2014/000814 (owned by the present applicant) disclose a spectrally selective panel that may be used as a windowpane and that is largely transmissive for visible light, but diverts a portion of incident infrared light to side portions of the panel where it is absorbed by solar cells to generate electricity.

### SUMMARY OF THE INVENTION

In a first aspect of the present invention there is provided a window unit for a building or structure, the window unit being arranged for generating electricity and comprising:

a panel having an area that is transparent for at least a portion of visible light and having a light receiving surface for receiving light from a light incident direction; and at least one series of solar cells, each solar cell being a bifacial solar cell and having opposite first and second surfaces each having an area in which light can be absorbed to generate electricity, the solar cells being positioned such that in use the first surfaces are oriented to receive light from the light incident direction and the second surfaces receive light from an opposite direction.

The solar cells of the first series of solar cells may be positioned exclusively at or near an edge region of the panel. Each solar cell may absorb, scatter or reflect 1000 of the incident light and may not comprise or entirely surround any region that is transmissive or partially transmissive for incident light.

The first surfaces may be oriented towards the light receiving surface of the panel. The window unit may be arranged such that the second surfaces of the solar cells predominantly are exposed to indirect (reflected) light (such as sunlight) and the first surfaces of the solar cells are positioned to receive largely light without prior reflection by a component of the window unit. Alternatively, the window unit may be arranged such that the second surfaces of the solar cells receive light from an interior of the building or structure.

The window unit comprises in one embodiment at least one light reflective surface that may face towards the panel or may form an angle of 90 degrees or less with the panel. The light reflective surface may be spaced apart from both the panel and the at least one series of solar cells and may be oriented parallel to the panel. The at least one reflective surface may face at least partially the second surfaces of the at least one of the solar cells where the light can be absorbed to generate electricity. The window unit may be arranged such that, in use, a portion of light incident on the receiving surface transmits through the panel towards the at least one light reflective surface and is then reflected by the at least one light reflective surface towards the second surfaces of the at least one of the solar cells where the light can be absorbed to generate electricity.

The second surfaces of the solar cells may face towards the at least one light reflective surface and the first surfaces of the solar cells may face away from the at least one light receiving surface. The panel may be positioned between the at least one series of solar cells and the at least one light receiving surface.

The at least one series of solar cells and the at least one light reflective surface may be positioned such that in use the second surfaces of solar cells are also exposed to incident light without prior reflection by a component of the window unit. The at least one light reflective surface is in one embodiment positioned such that a gap is defined between the second surfaces of the solar cells and the at least one light reflective surface.

The at least one light reflective surface may be positioned within a projection of a circumference of the panel in a direction of a surface normal of the panel. Further, a projection of the at least one series of solar cells in the direction of the surface normal of the panel may partially or entirely overlap with the at least one reflective surface.

The window unit may have an edge and the at least one series of solar cells may be positioned at and along the at least one edge. The at least one light reflective surface may be elongated and may also be positioned at and along the edge of the window unit. The at least one reflective surface is in one embodiment elongated and positioned at and along the edge of the window unit, but is spaced apart from the edge of the window unit. For example, the light reflective surface may be spaced apart from the edge by a distance in the range of 1 -10 cm, such as 2 - 8 or 3 - 6 cm.

The window unit may further comprise a frame structure supporting the panel and the at least one series of solar cells. The at least one light reflective surface may be positioned on the frame structure, a panel or another component of the window unit. The light reflective surface may be a surface of a frame structure or may be a surface of a separate component that is supported by the frame structure.

The light reflective surface may comprise a suitable dielectric coating or a coating of a metallic material. The light reflective surface may have a reflectivity of greater than 70%, 80%, 90%, 95% or even 99% of the incident light at a wavelength within and infrared or visible wavelength range.

In one embodiment the solar cells may be attached to the panel at their first surfaces to a panel surface that is opposite the light receiving surface such that light received by light receiving surface of the panel propagates through at least a portion of the panel before reaching the first surfaces of the solar cells.

In one embodiment the window unit comprises a plurality of series of solar cells each extending along a respective edge of the panel. Each series of the solar cells may be provided in the form of a narrow strip that only extends along, and in the proximity of, the respective edge such that a central area of the panel corresponds to an area in which no solar cells are positioned and which is at least largely transparent for visible light.

The at least one series of solar cells may be positioned in the proximity of edges of the panel such that the central area that is at least largely transparent for at least a portion of visible light is at 5, 10, 15, 20, 50, 100 or even 500 × larger than an area of the panel at which the series of the solar cells are positioned.

The solar cells may be positioned in an overlapping relationship or in a shingle-like arrangement.

The panel may be a first panel and the window unit may comprise a second panel having an area that is transparent for at least a portion of visible light. The at least one series of solar cells may be positioned between the first and the second panel.

The first surface of each solar cell may be directly or indirectly bonded to the first panel and the second surface of each solar cell may be directly or indirectly bonded to the second panel whereby each solar cell is sandwiched between the first and second panels. In this embodiment both the front and also the rear surfaces of the device are surfaces of the first or second panel (which may be glass panels), which has the advantage of protecting the solar cells and also has the advantage of providing reliable (vacuum) sealing surfaces for window application.

The frame may be arranged to support the first and the second panels, which may be spaced apart from one another. The at least one series of solar cells may be positioned between the first panel and the second panel.

The window unit may comprise at least one series of further solar cells that is positioned at at least one edge surface of the panel, or at least one of the first and second panels, and oriented substantially perpendicular to the light receiving surface facing towards the edge surface of the panel, or at least one of the first and the second panels, whereby the at least one series of further solar cells is positioned to receive light that travelled through the edge surface of the panel or at least one of the first and second panels.

The first or second panel may further comprise a diffractive element and/or luminescent material in order to facilitate redirection of incident infrared light to edges of the second panel.

The series of further solar cells may be positioned to receive at least a portion light redirected by the diffractive element and/or the luminescent material. The deflection of infrared radiation by the diffractive element has the further advantage that transmission of infrared radiation into buildings (when the panel is used as a window pane) can be reduced, which consequently reduces overheating of spaces within the building and can reduce costs for air conditioning.

Alternatively or additionally, the window unit may comprise at least one reflective edge element that is positioned at at least one edge surface of the panel, or at least one of the first and second panels, and oriented substantially perpendicular to the light receiving surface facing towards an edge surface of the panel, or at least one of the first and the second panels, whereby the at least one series of further solar cells is positioned to reflect light that travelled through the edge surface of the at least one of the first and second panel back into the at least one of the first and second panel thereby increasing likelihood that the light will be absorbed by one or more of the solar cells.

The window unit may also comprise further reflective elements located at edges surfaces of the panel, or at least one of the first and second panels, and being oriented substantially parallel to the panel and such that the further reflective elements and the reflective edge elements together form an arrangement that has a substantially cup-shaped cross-sectional shape at the edge surface.

The at least one reflective edge element and the further reflective elements may be provided in any suitable form, but in one embodiment comprise, or are provided in the form of, a reflective coating such as a metallic coating comprising aluminium or silver.

In one embodiment the at least one series of second solar cells are positioned at the second panel. In this embodiment the second solar cells may or may not be bifacial solar cells and may be positioned along and in the proximity of an edge of the second panel and facing the light receiving surface of the first panel.

The second solar cells may be bonded to the second panel, such as directly bonded, in a manner such that an airgap between the second solar cells and the second panel is avoided. The second series of solar cells may be positioned at and along an edge of the second panel.

In one alternative embodiment the window unit comprises a tapered extension that is attached, or forms a portion of, one or more panels of the window unit. For example, the second panel may comprise two or more parallel component panels and the tapered extension may be attached to an edge, or may form a part of, the two or more parallel component panels. The tapered extension has in this embodiment opposite first and second side portions that define an angle between them and define the tapered shape, which may or may not be tapered substantially to a point in cross-section. The window unit may in this embodiment comprise first and second series of solar cells each being bifacial and having first and opposite second surfaces for receiving light and generating electricity. In this embodiment the second surfaces of the solar cells may face, and may be attached to, the side portions of the tapered extension and may be positioned to receive light that travelled through edges of the one or more panels. The window unit is in this embodiment arranged such that the first surfaces of the solar cells receive light either from the incident light direction or from a substantially opposite direction, such as from an interior of the building or structure.

The tapered extension may be an attachment that is substantially prism-shaped in cross-section. Alternatively, the panel or may be tapered at edges such that the tapered extension forms a portion of the panel. The panel may comprise parallel component panel portions and further comprises a diffractive element and/or luminescent material arranged to facilitate redirection of incident infrared light to edges of the panel.

The first and second surfaces of the tapered extension may form an angle in the range of 1-5, 5-10, 10-15 or 15-20 degrees.

The at least one series of solar cells may also comprise flexible and/or bendable solar cells. In one specific embodiment of the present invention the at least one series of solar cells comprises bendable bifacial solar cells that are bent around a tip of the tapered extension.

In any embodiment of the present invention the solar cells may be bonded to panel surfaces or the tapered extension in a manner such that an airgap between the solar cells and the panel surfaces or between the solar cells and the tapered extension is avoided. An adhesive may be used for bonding. In one embodiment the adhesive has a refractive index that at least approximates that of the panel material or the material of the tapered extension, which may for example be glass or a suitable polymeric material. Alternatively, the solar cells may have an outer layer of a polymeric material, such as ethylene-vinyl acetate (EVA) or another suitable material. The solar cells may be directly bonded to panel surfaces or surfaces of the tapered extension. For example, if the solar cells comprise a layer of EVA or another suitable material, that material may be slightly softened and then adhered directly to the panel surfaces or surfaces of the tapered extension. As a gap between the panel or the tapered extension and the solar cells is avoided, intensity losses of light propagating from the panel into the solar cell are reduced.

The solar cells may be silicon-based solar cells, but may alternatively also be based on any other suitable material, such CIGS or CIS, GaAs, CdS or CdTe.

The building or structure may be an office building, a residential building, a commercial building, a glasshouse or any other type of building. Further, the building or structure may be a mobile structure, such as a vehicle, train carriage, aeroplane or the like.

The window unit may form an integrated glass unit, such as a double or triple glassed unit.

In any one of the above-described embodiments the panel or panels (such as the first and second panel) may be formed from glass or a suitable polymeric material.

In one specific embodiment of the present invention the panel or panels comprises further photovoltaic material. The further photovoltaic material may be positioned in, at, or in the proximity of panel material. The further photovoltaic material may be distributed over a surface, such as the receiving surface or an opposite surface, of the panel or at least one of the panels. The further photovoltaic material may be distributed between transmissive areas that are void of the further photovoltaic material such that features of the further photovoltaic material are sufficiently narrow to be at least largely invisible to the naked eye.

The further photovoltaic material has the advantage that no or only minimal obstruction of a view through the panel or at least one of the panels. Further, a relatively large portion of the total area of the panel or at least one of the panels can be used for generating electricity even though the panel appears to be at least largely transparent to the naked eye.

In second aspect of the present invention there is provided a window unit for a building or structure, the window unit being arranged for generating electricity and comprising:
a panel having an area that is transparent for at least a portion of visible light; and
at least one series of solar cells;
wherein the panel comprises further photovoltaic material positioned in, at, or in the proximity of panel material, the further photovoltaic material being distributed over a surface of the panel and between transmissive areas that are void of the further photovoltaic material such that features of the further photovoltaic material are sufficiently narrow to be at least largely invisible to the naked eye.

The following introduces optional features for the invention in accordance with the first and second aspects.

Features of the further photovoltaic material may have a diameter of 100 to 80, 80 to 60, 60 to 40, 40 to 20 or 20 to 10 micrometres. The transmissive areas between these features may have a diameter of 100 to 80, 80 to 60, 60 to 40, 40 to 20 or 20 to 10 micrometres.

The further photovoltaic material may form a pattern. For example, the further photovoltaic material may form a further diffractive element that is arranged to absorb a portion of received light to generate electricity and deflect a portion of the received light towards at least one edge surface of the panel material. The further diffractive element may comprise a periodic or quasi-periodic arrangement of the further photovoltaic material.

Throughout this specification the term “quasiperiodic arrangement” is used for an arrangement that includes a periodic component and also a non-periodic component that may be randomly distributed.

The further diffractive element may be a further diffractive grating having a period of 200 micrometres or less, such as less than 150, 100, 80, 60 or 40 micrometres. The further diffractive element may be arranged such that predominantly light having a wavelength in an infrared wavelength range is deflected towards the at least one edge surface. The further diffractive element and the panel material may be arranged such that at least a portion of the deflected light is guided within the panel material towards an edge surface of the panel or at least one of the panels.

The at least one series of further solar cells that may be positioned at at least one edge surface of the panel, or at least one of the panels, and may be oriented substantially perpendicular to the light receiving surface facing towards the edge surface of the panel, or at least one of the panels, and may be positioned to receive at least a portion of the light deflected by the further diffractive element towards the edge surface such that additional electricity can be generated.

The further photovoltaic material may be provided in the form of a continuous material or may comprise interconnected material portions. For example, the further photovoltaic material may comprise lines or randomly shaped or oriented material or a pattern of material with at least largely transmissive materials between the material.

The transmissive material areas may have any suitable shape (such as any regular or an irregular shape).

In one specific embodiment, the further photovoltaic material forms a pattern in a plane and comprises features that extend across at least a portion (such as the majority) of the panel material. The features of the further photovoltaic material may occupy 1% - 5%, 5% - 20%, 20% - 40%, 40% - 60%, or 60 -80% or more of an area (in a plane that is typically parallel to the receiving surface) of the diffractive element.

In one embodiment the further photovoltaic material is provided in the form of a continuous layered structure thin film material on the panel or at least one of the panels and transmissive material areas are then formed for example using laser ablation or a suitable etching process.

The invention will be more fully understood from the following description of specific embodiments of the invention. The description is provided with reference to the accompanying drawings.

### BRIEF DESCRIPTION OF THE DRAWINGS

FIG. 1 is a schematic top view of a window unit in accordance with an embodiment of the present invention;

FIGS. 2 - 14 are schematic cross-sectional representations of portions of the window unit in accordance with embodiments of the present invention;

FIG. 15 is a schematic representation of a component of a window panel in accordance with an embodiment of the present invention; and

FIG. 16 is schematic cross-sectional representations of portions of the window unit in accordance with a further embodiment of the present invention.

### DETAILED DESCRIPTION OF EMBODIMENTS

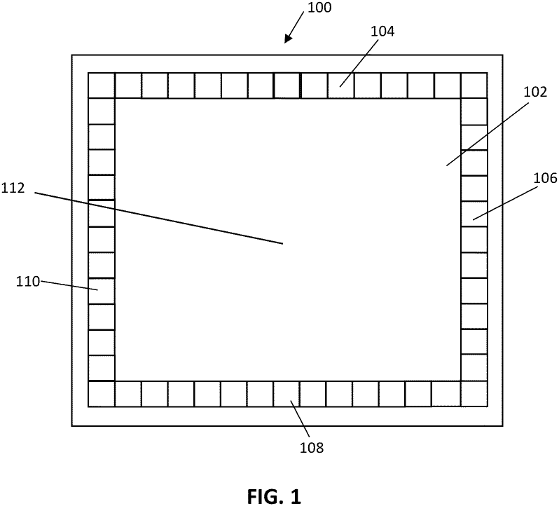

Referring initially to FIG. 1, there is shown a schematic top view of a window unit for generating electricity 100 in accordance with an embodiment of the present invention. The window unit 100 comprises a panel 102 and in this embodiment four series of solar cells 104 106, 108,110 are positioned at respective edges of the panel 102. The four series of solar cells 104 106, 108, 110 are bifacial solar cells. Each bifacial solar cell has a first surface for receiving light and generating electricity and an opposite second surface for receiving light and generating electricity of each solar cell faces. The first surface of each solar cell solar faces a light receiving surface of the panel 102 and the second surface faces in this embodiment an interior of a building of or structure to which the window unit may be attached. The solar cells together surround an area of the panel that is at least largely transmissive for light.

The material of the panel 102 is transmissive for at least 70%, 80%, or 90% of incident visible light (limited by the transmissivity of the panel material, such as glass). The solar cells are only positioned at edges of the panel 102 such that only at edges of the panel 102 the transmission of incident light is obstructed by the solar cells.

The first surfaces of the solar cells are in this example adhered to the panel 102 such that no air gap is present between the solar cells and the panel 102. In this example the solar cells 112 comprise outer EVA layers. Prior to adhering the solar cells 112 to the panel 102, the EVA is slightly softened (by the careful application of heat) and then the solar cells 112 are pressed against the panel 102. Once the softened EVA has hardened again, the solar cells are adhered to the panel 102 without the need of an additional adhesive.

The panel 102 may have any shape, but in one specific embodiment is rectangular and may be square. The panel 102 may be formed from suitable glass or polymeric materials.

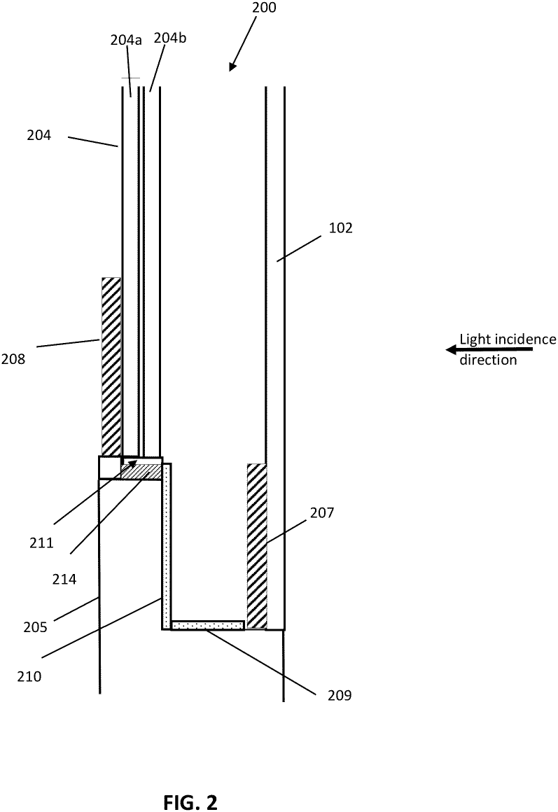

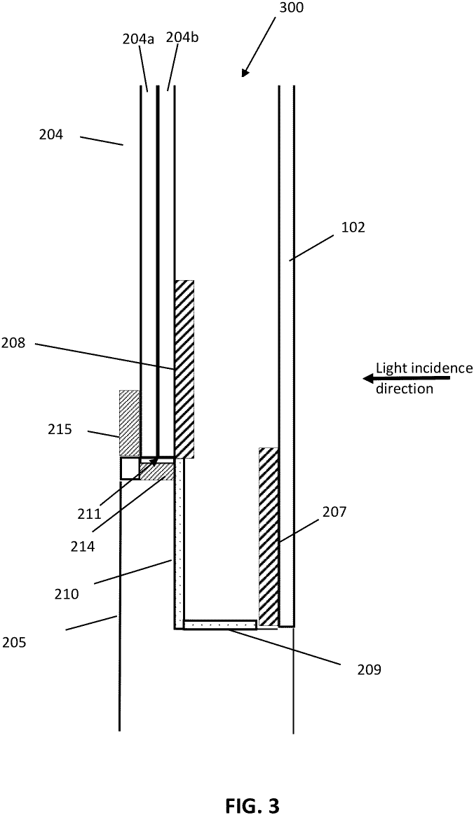

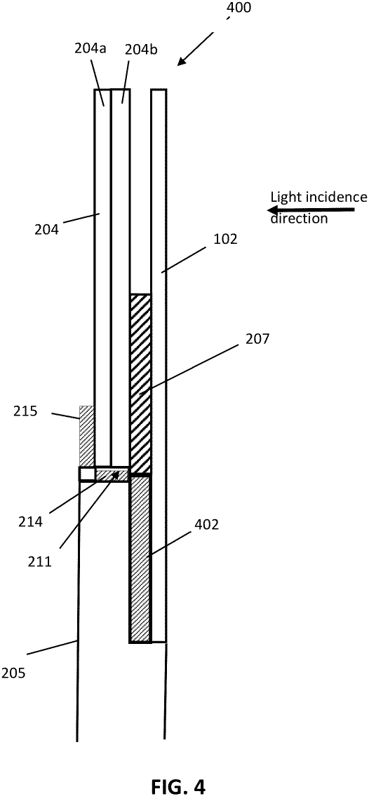

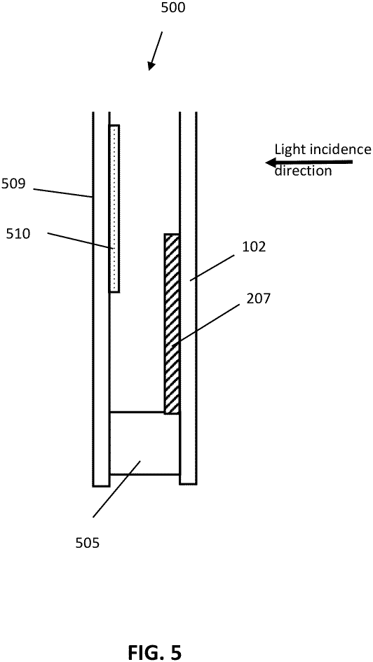

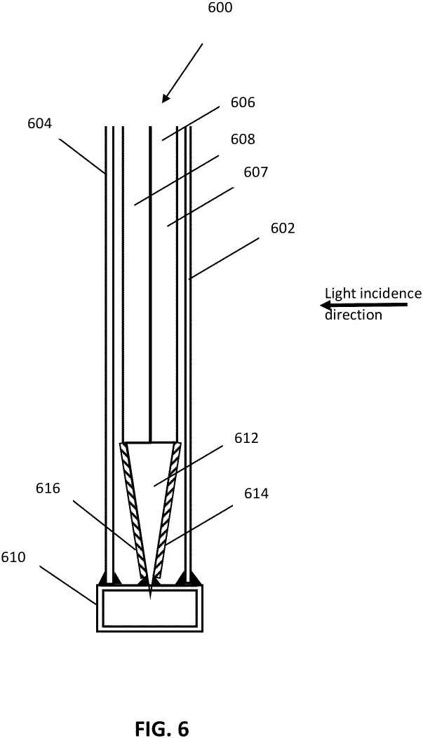

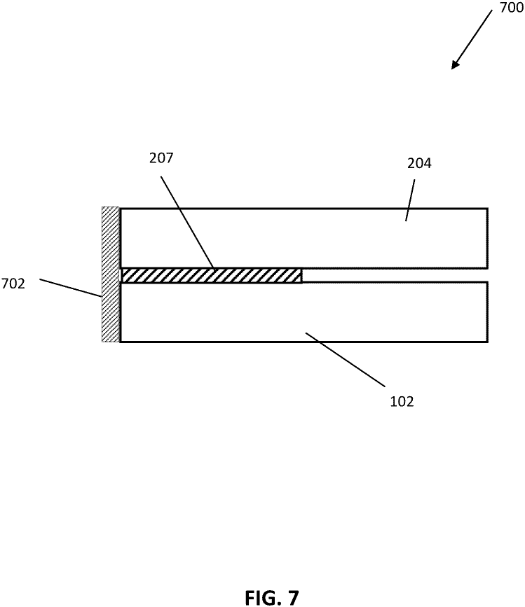

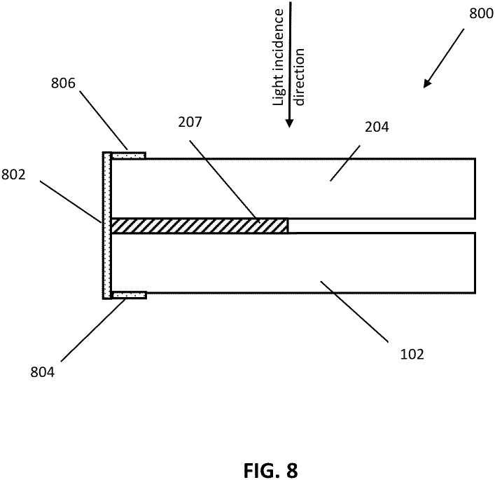

Turning now to FIG. 2, there is shown a cross-sectional view of a portion of a window unit 200 in accordance with another embodiment of the present invention. The window unit 200 comprises the panel 102 with first solar cells 207 and panel 204 with second solar cells 208. The solar cells 207 and 208 each are parts of series of solar cell that that together surround an area of the panel 102 and 204, respectively, that is at least largely transmissive for light (similar to the embodiment illustrated in FIG. 1). The solar cells 207 and 208 are bifacial solar cells and in this embodiment the solar cells 207 and 208 and directly adhered to surface portions of the panel 202 and 204, respectively.

The window unit 200 also comprises reflective portions 209 and 210. The reflective portions have in tis embodiment metallic surfaces (which may be the surfaces of AL or AG coatings) which have high reflectivity. The reflective portions 209, 210 are positioned on a frame structure 205 and in a cavity behind the bifacial solar cells 207. The reflective portions 209 and 210 encircle a space behind the bifacial solar cells 207. The reflective portions 209, 210 are positioned such that a significant portion of light that is received within a gap between the reflective portions 210 and the solar cells 207 is directed to the second surfaces of the bifacial solar cells 207 where it can be absorbed to generate electricity.

In this embodiment the bifacial solar cells 208 are positioned such that the second surface of the bifacial solar cells 208 face an interior of a building or structure to which the window unit 200 is attached. The second surfaces of the bifacial solar cells 208 consequently are positioned to receive diffuse or also direct light from the interior of the building or structure and can consequently generate additional electricity.

The frame structure 205 is arranged to hold the panels 102 and 202 and the series of solar cells in position.

In the embodiment shown in FIG. 2 the panel 204 is a laminate structure having two sub-panels 204a and 204b. The sub-panels 204a and 204b mate with each other to form the panel 204. Disbursed between panels 204a and 204b is an interlayer of polyvinyl butyral (PVB), which in this embodiment also includes a light scattering element. In this embodiment the light scattering element comprises a luminescent scattering powder embedded in the PVB, which also an epoxy that provides adhesive. The panel 204 also includes a diffraction grating that is arranged to facilitate redirection of light towards edge region of the panel 204 and guiding of the light by total internal reflection.

Further details of the luminescent and/or scattering material are described in PCT international applications numbers PCT/AU2012/000778 and PCT/AU2012/000787 (owned by the present applicant and which are herewith incorporated by cross-reference.

It should be appreciated that the panel 204 could have any number of panes with any number of interlayers. In some embodiments the panel 204 may comprise a single piece of optically transmissive material such as glass.

The panel 204 has an edge 211 that has a plane which is transverse to the light receiving surface of the panel 102. In the embodiment of FIG. 2, the angle between the edge 211 and the light receiving surface is 90°.

The window unit 200 also has series of third solar cells 214. The series of third solar cells 214 face edge 211 of the panel 204. The series of third solar cells 214 substantially surround the panel 204 and are positioned to receive light that is redirected by the scattering material and/or the diffractive element (not shown) to the edges (such as edge 211) of the second panel 204.

In this embodiment the solar cells of the third series are not bifacial solar cells, but each have a single light receiving surface which faces the edge 211 of the panel 204.

Referring now to FIG. 3, a further embodiment of the window unit 300 is now described. The window unit 300 is related to the window unit 200 described with reference to FIG. 2 and like reference numerals are used for like components. However, in contrast to the window unit 200, the bifacial solar cells 208 are not positioned at a surface of sub-panel 204a, but are attached to a surface of sub-panel 204b and consequently positioned between the panels 102 and 204. The first surfaces of the bifacial solar cells 208 are positioned to receive incident and scattered light from the light that travelled through only a single panel 102 (rather than also through the panel 204). Further, the second surfaces of the bifacial solar cells 208 are positioned to receive light form an interior of the building or structure and also light that is scattered out of the panel 204 near the edge 211 of the panel 204 and also light that is reflected by the solar cells 214.

In this embodiment the window unit 300 also comprises further solar cells 215, which may or may not be bifacial solar cells. The solar cells 215 have first surfaces at which they are attached to the panel 204 and which are positioned to receive light that is scattered out of the panel 204 near the edge 211 of the panel 204 and also light that is reflected by the solar cells 214. If the solar cells 215 are bifacial solar cells, the solar cells 215 will in use also receive light from an interior of the building or structure to which the window unit 300 is attached.

Referring now to FIG. 4, a window unit 400 in accordance with another embodiment of the present invention is now described. The window unit 400 is related to the window units 200 and 300 described with reference to FIGS. 2 and 3 and like reference numerals are used for like components. In this embodiment the bifacial solar cells 207 are sandwiched between the panels 102 and 204 with the first surfaces of the solar cells 207 adhered to the panel 102 and the second surfaces of the solar cells 207 adhered to the panel 204. The first surface of the panel 207 is positioned to receive light that travelled through the panel 102 from the light incidence direction (from an outside region of the building or structure) and the second surface is positioned to receive light from an interior portion of the building or structure. The window unit 400 also comprises further series of solar cells 402 positioned at edges of the panel 102 and surrounding the bifacial solar cells 207 in a plane behind the panel 102. The solar cells 402 are not bifacial and are sandwiched between a portion of the frame 205 and the panel 102. The window unit further comprises solar cells 214 and 215, which are positioned and arranged as discussed above with reference to FIG. 3.

FIG. 5 illustrates a window unit 500 in accordance with a further embodiment of the present invention. In this embodiment the first surfaces of the bifacial solar cells 207 are adhered to the panel 102. The solar cells 207 are positioned at edges of the panel 102 and form series. The series of the bifacial solar cells 207 surround a central area of the panel which is transmissive for visible light. The window unit 500 also comprises a frame 505, which supports components of the window unit 500. A second panel 509 supports a reflective portion 510, which is positioned to direct some of the incident light, which travelled through the panel 102, to the second surface of the solar cell 207, where the light can be absorbed to generate electricity.

FIG. 6 illustrates a window unit 600 in accordance with another embodiment of the present invention. The window unit 600 comprises outer glass panels 602 and 604 and inner glass panels 606 and 608. A frame 610 supports components of the window unit 600. Further, the window unit 600 comprises a tapered extension, which in this embodiment is provided in the form of a prism-shaped body 612, such as a prism shaped body formed from a suitable polymeric material or glass. The prism-shaped body 612 is adhered to the panel 606 using an optical adhesive, which has a refractive index (when cured) which at least approximates of equals the refractive index of the material of the panels 606 and the prism-shaped body 612. A person skilled in the art will appreciate that in a variation of the described embodiment the tapered extension 612 may also be formed from bevelled edge portions of the panel 606.

Attached to opposite side portions of the tapered extension are bifacial solar cells 614 and 616. The bifacial solar cells 614 and 616 have first surfaces at which they are attached to the prism-shaped extension 612 in a manner such that a gap is avoided. The first surface of the bifacial solar cells 614, 616 are consequently positioned to receive light that travelled through edges of the panel 606. Further, the bifacial solar cells 614 and 616 have second surfaces that are positioned to receive light form a light incidence direction and from an interior portion of the building or structure to which the window unit is in use attached.

The panel 606 comprises sub-panels 606 and 608, which mate with each other to form the panel 606. Disbursed between sub-panels 607 and 608 is an interlayer of polyvinyl butyral (PVB), which in this embodiment also includes a light scattering element. In this embodiment the light scattering element comprises a luminescent scattering powder embedded in the PVB, which also an epoxy that provides adhesive. The panel 606 also includes a diffraction grating that is arranged to facilitate redirection of light towards edge region of the panel 606 and guiding of the light by total internal reflection.

In a variation of the described embodiment the bifacial solar cells 614 and 616 are formed from a flexible and/or bendable material and may be formed on a common substrate. The bifacial solar cells 614 and 616 may also be portions of the same solar cell which is bendable and may be bent around a tip of the prism shaped body 612. For further details concerning flexible and/or bendable solar cells reference is being made to the applicant’s co-pending PCT international application no. PCT/AU2018/051263, which is herewith incorporated by cross-reference.

FIG. 7 illustrates a window unit 700 in accordance with another embodiment of the present invention. In this embodiment the bifacial solar cells 207 are sandwiched between the panels 102 and 204. The first surfaces of the bifacial solar cells 207 are adhered to the panel 102 and the second surfaces of the solar cells 207 are adhered to the panel 204. Similar to the embodiment illustrated with reference to FIGS. 3 and 4, the window unit 700 comprises solar cells 702 which face edge surfaces of the panels 102 and 204 and have first surfaces attached to the panels 102 and 204. In this embodiment the solar cells 702 are positioned to receive light that is directed through the edge surfaces of the panels 102 and 204. The panels 102 and 204 may comprise suitable luminescence and or scattering material and/or diffractive gratings to facilitate redirection of incident light towards the edge surfaces as described above with reference to panel 606.

FIG. 8 illustrates a window unit 800 in accordance with another embodiment of the present invention. The window unit 800 is a variation of the above-described window unit 700 and like reference numerals are used for like components. However, instead of the solar cells 702 the window unit 800 comprises reflective portions 802, 804 and 806. The reflective portion 802 faces the edge surfaces of the panels 102 and 204 and is positioned to reflect light that is redirected through the edge surfaces of the panels 102 and 204 back into the panels 102 and 204 to enable absorption of at least a portion of the reflected light by the bifacial solar cells 207. The reflective portions 804 and 806 are positioned to reflect light that is scattered out of the panels 102 and 204 at edge regions of the panels 102 and 204 back into the panels 102 and 204 to enable absorption of at least a portion of the reflected light by the bifacial solar cells 207. In this embodiment the reflective portions 802, 804 and 806 form an arrangement that has a cup-shaped cross-sectional shape. The reflective portions 802, 804 and 806 may take any suitable form, but in this embodiment are metallic coatings (such as aluminium or silver coatings) that are applied to surface portions of the panels 102 and 204. In a further variation, the window unit 800 may not comprise the reflective portions 804 and 806.

Turning now to FIG. 9, a window unit 900 in accordance with a further embodiment of the present invention is now described. The window unit 900 is related to the window unit 700 described above and like reference numerals are used for like components. In this embodiment the window unit 900 is a triple-glazing arrangement and comprises a third panel 902 and further bifacial solar cells 904. The bifacial solar cells 904 are sandwiched between, and adhered to, the panels 204 and 902. The window unit 900 also comprises solar cells 906, which face edge surfaces of the panels 102, 204 and 902 and have first surfaces attached to the panels 102, 204, 902 and 906. The solar cells 906 are positioned to receive light that is directed through the edge surfaces of the panels 102, 204 and 906. Similar to the window unit 700, the panels 102, 204 and/or 902 may comprise suitable luminescence and/or scattering material and/or diffractive gratings to facilitate redirection of incident light towards edges of the panels 102, 204 and 902.

Referring now to FIG. 10, a window unit 1000 in accordance with a further embodiment of the present invention is now described. The window unit 1000 is a variation of the above-described window unit 900 and like reference numerals are used for like components. However, instead of the solar cells 906 the window unit 1000 comprises reflective portions 1002, 1004 and 1006. The reflective portion 1002 faces the edge surfaces of the panels 102, 204 and 902 and is positioned to reflect light that is redirected through the edge surfaces of the panels 102, 204 and 902 back into the panels 102, 204 and 902 to enable absorption of at least a portion of the reflected light by the bifacial solar cells 207 and 904. The further reflective portions 1004 and 1006 are positioned to reflect light that is scattered out of the panels 102, 204 and 902 at edges of the panels 102, 204 and 902 back into the panels 102, 204 and 902 to enable absorption of at least a portion of the reflected light by the bifacial solar cells 207 and 904. The reflective portions 1002, 1004 and 1006 form an arrangement that has a cup-shaped cross-sectional shape and are provided in the form of reflective coatings (such as metallic coatings comprising aluminium or silver). The reflective portions 1002, 1004 and 1006 are in this embodiment coatings applied to surface portions of the panels 102, 204 and 902. In a variation, the window unit 1000 may not comprise the reflective portions 1004 and 1006.

FIG. 11 illustrates a window unit 1100 in accordance with a further embodiment of the present invention. The window unit 1100 is in this embodiment a quadruple glazing arrangement and relates to the window unit 700 described above and like components are given like reference numerals. The window unit 1100 relates to a combination of two of the window units 700 positioned in a parallel and separated by a spacer 1102. The spacer 1102 may be provided in any suitable forms and may for example comprise bars formed from a suitable metallic or polymeric material which may have reflective surfaces. In this embodiment the window unit 1100 comprises solar cells 1104 that face edge surfaces of the panels 102 and 204 and have first surfaces attached to the panels 102 and 204. The solar cells 1104 are positioned to receive light that is directed through the edge surfaces of the panels 102, 204. The panels 102, 204 may comprise suitable luminescence and or scattering material and/or diffractive gratings to facilitate redirection of incident light towards edges of the panels 102, 204. FIG. 12 illustrates a window unit 1200 in accordance with yet another embodiment of the present invention. The window unit 1200 is a variation of the above-described window unit 1100 and like reference numerals are used for like components. However, instead of the solar cells 1102 the window unit 1200 comprises reflective portions 1202, 1204 and 1206. The reflective portions 1202 face the edge surfaces of the panels 102 and 204 and are positioned to reflect light that is redirected through the edge surfaces of the panels 102 and 204 back into the panels 102 and 204 to enable absorption of at least a portion of the reflected light by the bifacial solar cells 207. The further reflective portions 1204 and 1206 are positioned to reflect light that is scattered out of the panels 102 and 204 at edges of the panels 102 and 204 back into the panels 102 and 204 to enable absorption of at least a portion of the reflected light by the bifacial solar cells 207. In this embodiment the reflective portions 1202, 1204 and 1206 form an arrangement that has a cup-shaped cross-sectional shape. The reflective portions 1202, 1204 and 1206 may take any suitable form, but are in this embodiment metallic coatings that are applied onto surface portions of the panels 102 and 204 (such as coatings comprising aluminium or silver). In a further variation, the window unit 1200 may not comprise the reflective portions 1204 and 1206.

The solar cells of the window units 200 - 1200 described with reference to FIGS. 2 - 12 are attached to panel surfaces in the same manner as described above in the context of the window unit 100. Surfaces of the solar cells are adhered to the panels such that no air gap is present between the solar cells and the panels. In the described examples the solar cells have outer EVA layers. Prior to adhering the solar cells to the panels, the EVA is slightly softened (by the careful application of heat) and then the solar cells are pressed against the panels. Once the softened EVA has hardened again, the solar cells are adhered to the panels without the need of an additional adhesive. However, a person skilled in the art will appreciate that alternatively an adhesive (such as an optical adhesive) can be used for adhering the solar cells to the surfaces of the panels. The adhesive has ideally a refractive index (when cured) which at least approximates or equals the refractive index of the material of the panels.

All panels and sub-panels of the above described embodiments are formed of low iron ultra-clear glass. Further, each of the above-described window units has panels that are transmissive for incident visible light (limited by the transmissivity of the panel material, such as glass). The solar cells are only positioned at edges of the panels such that only at edges of the panels the transmission of incident light is obstructed by the solar cells.

The solar cells of each of the described embodiments may be silicon-based solar cells, but can alternatively also be based on any other suitable material such CdS, CdTe, GaAs, CIS or CIGS.

FIG. 13 illustrates a further embodiment of the present invention. FIG. 13 shows a window panel 1300 comprising a top panel 1302 and a bottom panel 1310. Bifacial solar cells 1304 are distributed along edges of the top panel 1302. Further, a diffractive grating 1306 is positioned at edges of the top panel 1302. The diffractive grating 1306 is in this embodiment a phase grating that is structured to facilitate direction of light incident on the top panel 1302 towards edge portions of the panel 1300. The diffractive grating 1302 may be embossed or otherwise formed (written) into a surface of the top panel 1302. Further, the panel window unit 1300 comprises a low-emissivity coating 1308, which in this embodiment is a double silicone coating and is reflective for light in an infrared wavelength range while largely transmissive for light in a visible wavelength range.

In one embodiment any one or more of the panels 102, 204, 204a, 204b, 602, 604 and 904 described above with reference to FIGS. 1 - 11 comprise further photovoltaic material which may be positioned on a panel surface and distributed over the panel surface. The further photovoltaic material is in one embodiment provided in the form of a thin film material, such as a thin film of a CIS or CIGS, but a person skilled in the art will appreciate that alternatively the further photovoltaic material may be provided in other forms (including any suitable conventional inorganic photovoltaic material and organic material, such as polymeric photovoltaic materials).

The further photovoltaic material will now be described with reference to FIG. 14, which shows a window panel 1400 in accordance with an embodiment of the present invention. In this embodiment the further photovoltaic material 1402 is provided in form of a thin film material deposited on a surface of the panel 1400, which is largely transparent for visible light. The photovoltaic material 1402 has voids 1403 and is structured such that it is invisible for the naked eye (the illustration of FIG. 14 is not to scale). The panel 1300 may replace any one of the panels 102, 204, 204a, 204b, 602, 604, 904 and 1302 described above with reference to FIGS. 1 to 13.

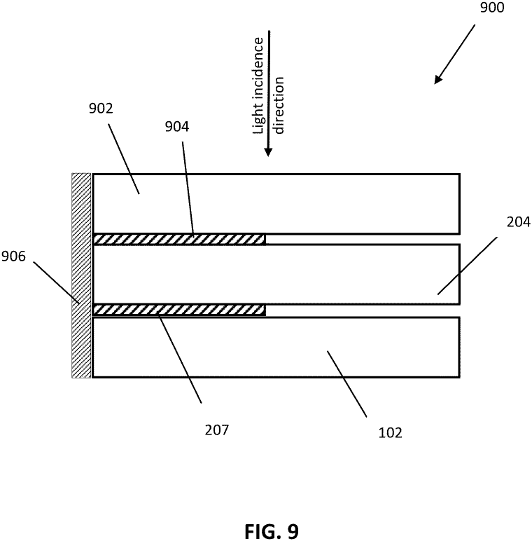

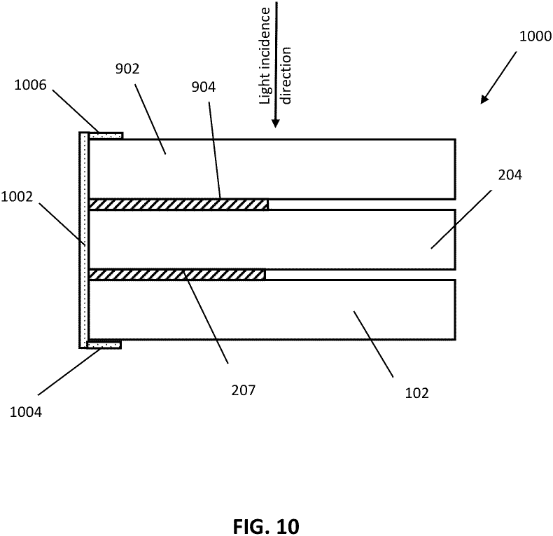

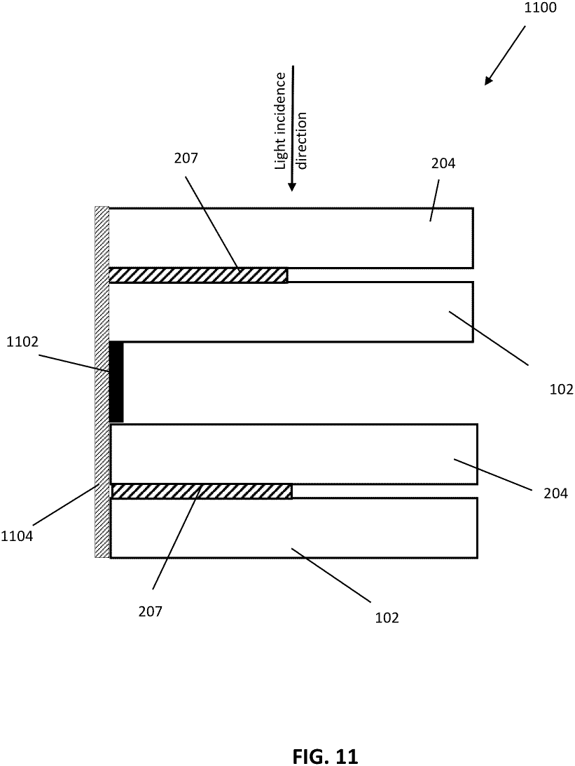

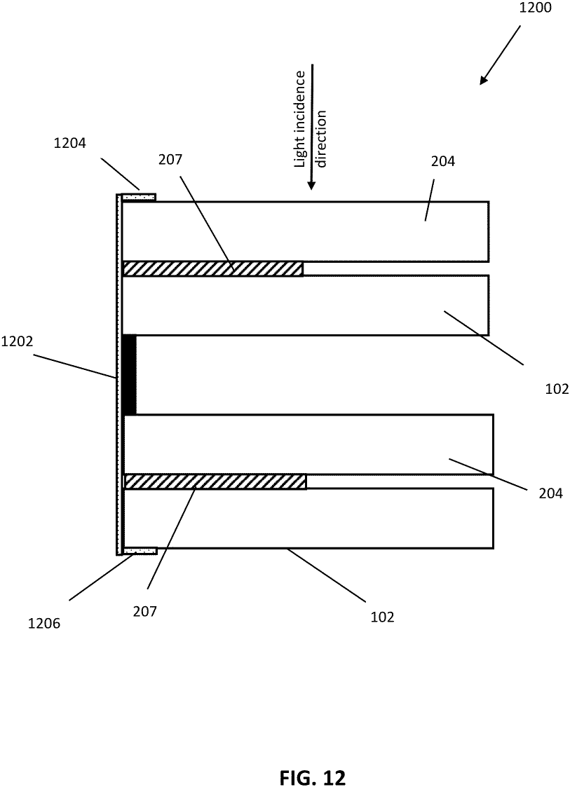

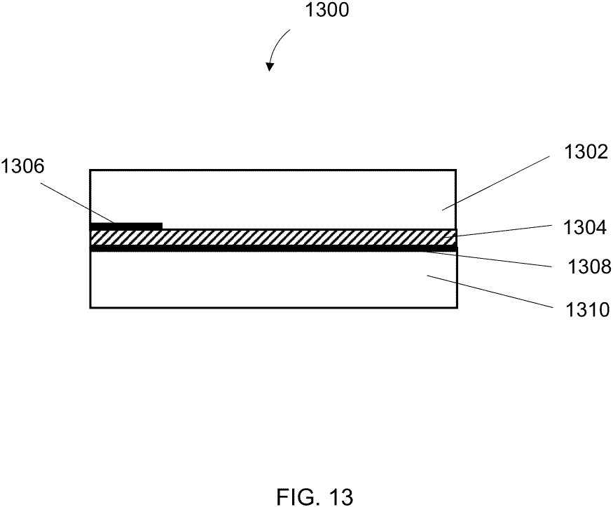

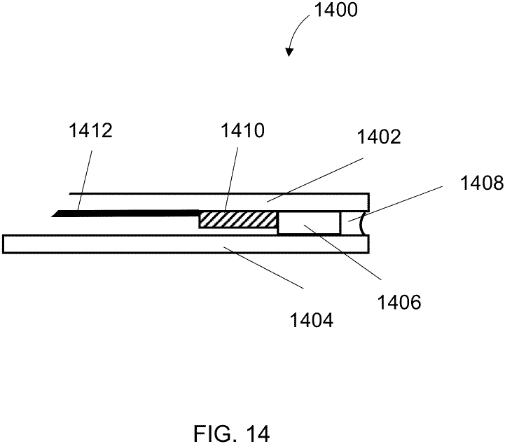

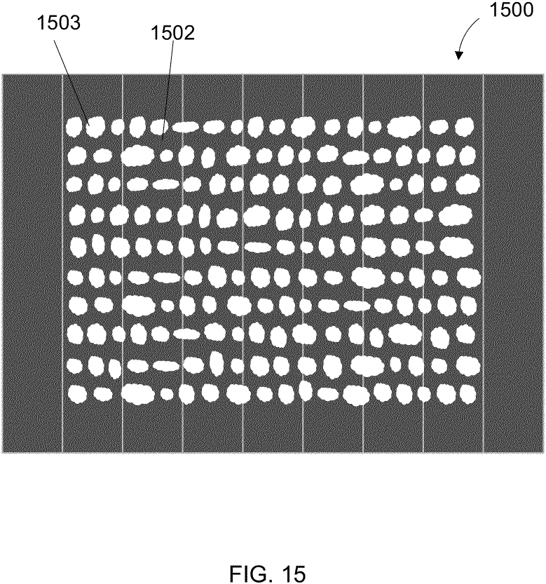

The further photovoltaic material forms in one embodiment a further diffractive grating, which is schematically illustrated in FIG. 15. The further diffractive grating 1500 is formed from a periodic or quasiperiodic arrangement of the further photovoltaic material and is arranged to absorb a portion of the received light to generate electricity and deflect a portion of the received light towards an edge surface of the panel material. Typically, the further photovoltaic material comprises lines or other structures 1502 that have a width that is narrower than 100 to 50 micrometres, such as 10 - 25 micrometres and are consequently invisible by the naked eye and surround or separated areas 1503 that are void of the photovoltaic material. The lines of other structures of the further diffractive grating are series connected. The further diffractive grating 1500 is in this embodiment arranged to facilitate re-direction of incident light towards an edge of the panel where the light can either be absorbed by the photovoltaic cells positioned as edges (such as the photovoltaic cells 214, 702, 614, 616, 906 and 1104 described above with reference to FIGS. 2, 3, 4, 6, 7, 9 and 11) or reflected by reflective portions (such as reflective portions 802, 804, 806, 1002, 1004, 1006, 1202, 1204, 1206 described above with reference to FIGS. 8, 10 and 12) .

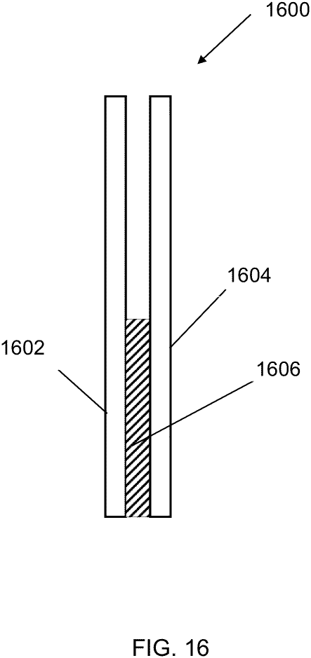

FIG. 16 illustrates a device in accordance with a further embodiment of the present invention. FIG. 16 shows the device 1600 having a first panel 1602 and a second panel 1604. The first and second panels 1602, 1604 are transmissive for at least 70% of incident visible light (limited by the transmissivity of the panel material, such as glass). The device 1600 comprises bi-facial solar cells 1606 positioned at edges of the panels 1602, 1604.

The solar cells 1606 each have a light receiving surface facing the panel 1602 and adhered to the panel 1602 such that no air gap is present between the solar cells 1606 and the panel 1602. Further, the solar cells 1606 each have a rear light receiving surface facing the panel 1604 and adhered to the panel 304. A sheet of excluded-volume-branched-polymers (EVB) or Ethylene tetrafluoroethylene (ETFE) is placed between the panels 1602 and 1604. In this example the solar cells 1606 comprise outer ETA layers. Prior to adhering the solar cells 1606 to the panels 1602 and 1604 and the panels 1602 and 1604 to each other, the ETA and the EVB or ETFE is slightly softened (by the careful application of heat) and then the panel 1602, 1604 are pressed together. Once the softened ETA has hardened again, the solar cells are sandwiched between, and adhered to, the panels 1602, 1604 without the need of an additional adhesive whereby a laminated structure is formed. The panels 1602, 1604 protect the solar cells 1606 and also provide reliable sealing surfaces at both front and rear sides of the device, which is advantageous for window applications.

It will be appreciated, however, that in variations of the described embodiments, the further photovoltaic material may alternatively comprise slightly larger features that may be visible to the naked eye. For example, the further photovoltaic material may alternatively have features between transmissive material areas that have a diameter of 100 - 200 micrometres. In this case the features may be sized such that they may be visible to the naked eye if closely inspected, but are sufficiently small such that they do not obstruct a view through the panel structure in a significant manner.

Further, a person skilled in the art will appreciate that in variations of the described embodiments the further photovoltaic material may not form a further diffractive element, but may be randomly arranged and may or may not form a pattern.

The following will describe the fabrication of the further photovoltaic material 1402. Formation of the further photovoltaic material 1402 may initially comprise providing transparent panels (such as glass panels), on which the CIS or CIGS is formed. Features of the further photovoltaic may be then formed by ablating portions of the CIS or CIGS material to form the above described transmissive material areas of the further photovoltaic material. For example, ablation may comprise photothermal ablation using one or more lasers. Formation of structures having a diameter of less than 20 micrometres is possible using laser ablation. Specifically, a UV wavelength laser of sufficient power is used to ablate locally the CIS or CIGS material, which breaks chemical bonds between molecules and residues are ablated from the surface leaving a transmissive material area (hole). A person skilled in the art will appreciate that in this manner extending structures may be formed by moving the further diffractive grating relative to the laser beam. Further, a series of lasers may be used for parallel ablation processes, which reduces production time.

Alternatively, the further photovoltaic material may be formed using reactive ion etching (RIE), such as deep RIE. In this case, initially CIS or CIGS solar cells are formed on a transparent panel portion, which is then covered by a suitable mask. The panel portion with the CIS or CIGS material and the mask is then placed in a chamber into which suitable gases are introduced for plasma etching using a radio frequency power source. Individual CIS or CIGS layer portions are then electrically connected using thin molybdenum wires or silver wires, such as silver nanowires, that may have a length of 100 micrometres and a thickness of 25 micrometres and are consequently invisible to the naked eye.

Wet etching may also be used to form the transmissive material areas in the further photovoltaic material. The formed CIS or CIGS material on a transparent panel is covered using a suitable mask that is largely resistant to a selected wet etching process. Etching below areas covered by the mask, which is a known problem for wet etching in particular when forming small structures, can be reduced by using suitable spray etching techniques.

Alternatively, wet etching may also be performed without the mask and using a technique similar to that of ink jet printing in which small droplets of the etching material are positioned directly onto the CIS or CIGS material to form the transmissive material areas.

The reference that is being made to PCT international applications numbers PCT/AU2012/000778, PCT/AU2012/000787, PCT/AU2014/000814 and PCT/AU2018/051263 does not constitute an admission that these documents are part of the common general knowledge in Australia or any other country.

1. A window unit for a building or structure, the window unit being arranged for generating electricity and comprising:
a panel having an area that is transparent for at least a portion of visible light and having a light receiving surface for receiving light from a light incident direction; and
at least one series of solar cells, each solar cell being a bifacial solar cell and having opposite first and second surfaces each having an area in which light can be absorbed to generate electricity, the solar cells being positioned such that in use the first surfaces are oriented to receive light from the light incident direction and the second surfaces receive light from an opposite direction.

2. (canceled)

3. The window unit of claim 1 wherein the first surfaces are oriented towards the light receiving surface of the panel and wherein the window unit is arranged such that the second surfaces of the solar cells receive light from an interior of the building or structure.

4. The window unit of claim 1 comprising at least one light reflective surface facing towards the panel or forming an angle of 90 degrees or less with the light receiving surface of the panel, the at least one light reflective surface being spaced apart from both the panel and the at least one series of solar cells.

5. The window unit of claim 4 wherein the window unit is arranged such that, in use, a portion of light incident on the receiving surface transmits through the panel towards the at least one light reflective surface and is then reflected by the at least one light reflective surface towards the second surfaces of the at least one of the solar cells where the light can be absorbed to generate electricity.

6. The window unit of claim 3 wherein the window unit is arranged such that a portion of light incident on the receiving surface transmits through the panel towards the at least one light reflective surface and is then reflected by the at least one light reflective surface towards the second surfaces of the at least one of the solar cells where the light can be absorbed to generate electricity.

7. (canceled)

8. The window unit of claim 3 wherein the at least one series of solar cells and the at least one light reflective surface are positioned such that the second surfaces of solar cells are also exposed to incident light without prior reflection by a component of the window unit.

9. The window unit of claim 3 wherein the at least one light reflective surface is positioned such that a gap is defined between the second surfaces of the solar cells and the at least one light reflective surface.

10. (canceled)

11. The window unit of claim 1 comprising a plurality of series of solar cells each extending along a respective edge of the panel.

12. The window unit of claim 1 wherein the panel is a first panel and the window unit comprises a second panel having an area that is transparent for at least a portion of visible light and wherein the at least one series of solar cells is positioned between the first and the second panel.

13. The window unit of claim 12 wherein the first surface of each solar is directly or indirectly bonded to the first panel and the second surface of each solar cell is directly or indirectly bonded to the second panel whereby each solar cell is sandwiched between the first and second panels.

14. The window unit of claim 1 comprising at least one series of further solar cells that is positioned at at least one edge surface of the panel, or at least one of the first and second panels, and oriented substantially perpendicular to the light receiving surface facing towards an edge surface of the panel, or at least one of the first and the second panels, whereby the at least one series of further solar cells is positioned to received light that travelled through the edge surface of the panel or at least one of the first and second panels.

15. The window unit of claim 1 comprising at least one reflective edge element that is positioned at at least one edge surface of the panel, or at least one of the first and second panels, and oriented substantially perpendicular to the light receiving surface facing towards an edge surface of the panel, or at least one of the first and the second panels, whereby the at least one series of further solar cells is positioned to reflect light that travelled through the edge surface of the panel, or at least one of the first and second panel back, into the panel, or at least one of the first and second panels thereby increasing likelihood that the light will be absorbed by one or more of the solar cells.

16. (canceled)

17. (canceled)

18. (canceled)

19. (canceled)

20. The window unit of claim 1 comprising a tapered extension that is attached, or forms a portion of, the panel of the window unit.

21. The window unit of claim 20 wherein the tapered extension has opposite first and second side portions that define an angle between them and define the tapered shape and wherein the window unit comprises first and second series of solar cells each being bifacial and having first and opposite second surfaces for receiving light and generating electricity.

22. (canceled)

23. The window unit of claim 21 wherein the second surfaces of the solar cells face, and are attached to, the side portions of the tapered extension and are positioned to receive light that travelled through edges of the one or more panels whereby the window unit is arranged such that the first surfaces of the solar cells receive light either form the incident light direction or form a substantially opposite direction.

24. (canceled)

25. (canceled)

26. The window unit of claim 1 wherein the at least one series of solar cells comprises flexible and/or bendable solar cells.

27. (canceled)

28. (canceled)

29. The window unit of claim 1 wherein the solar cells are bonded to panel surfaces of the tapered extension in a manner such that an airgap between the solar cells and the panel surfaces or between the solar cells and the tapered extension is avoided.

30. The window unit of claim 1 wherein the panel or at least one of the first and second panels comprises further photovoltaic material and wherein the further photovoltaic material is positioned in, at, or in the proximity of a surface of the panel, or at least one of the first and second panels, the further photovoltaic material being distributed along the surface of the panel or at least one of the panels and between transmissive areas that are void of the further photovoltaic material, the further photovoltaic material being structured such that features of the further photovoltaic material are sufficiently narrow to be at least largely invisible to the naked eye.

31. (canceled)

32. The window unit of claim 30 wherein the further photovoltaic material forms a pattern.

33. (canceled)

34. (canceled)

35. (canceled)

36. A window unit for a building or structure, the window unit being arranged for generating electricity and comprising:
a panel having an area that is transparent for at least a portion of visible light; and
at least one series of solar cells;
wherein the panel comprises further photovoltaic material positioned in, at, or in the proximity of panel material, the further photovoltaic material being distributed over a surface of the panel and between transmissive areas that are void of the further photovoltaic material such that features of the further photovoltaic material are sufficiently narrow to be at least largely invisible to the naked eye.
